(19) United States
(12) Patent Application Publication
(10) Pub. No.: US 2004/0179710 A1
(43) Pub. Date: Sep. 16, 2004

(54) Audio speaker system

(76) Inventors: Robert P. Farinelli JR., Lexington, KY (US); Ken Salyer, Lexington, KY (US); Lane Gould, Lexington, KY (US); Keith Chambers, Lexington, KY (US)

Correspondence Address: Crawford Maunu PLLC, Suite 390, 1270 Northland Drive, St. Paul, MN, 55120, US

(21) Appl. No.: 10/746,247

(22) Filed: Dec. 22, 2003

Related U.S. Application Data
(60) Provisional application No. 60/435,103, filed on Dec. 20, 2002.

(51) Int. Cl. H04R 1/02; H05K 5/00

(52) U.S. Cl. 381/386; 381/87; 181/150

(57) ABSTRACT

A speaker system and approach facilitates flexible installation and removal of an audio speaker into a structure. According to an example embodiment of the present invention, a speaker system includes mounting hardware and audio components with a fastening arrangement that facilitates the fastening of the mounting hardware to a structure and the audio components to the mounting hardware. The speaker system is amenable to a one-piece installation wherein the audio components are coupled to the mounting hardware during installation, as well as a two-piece installation wherein the mounting hardware is attached to the structure separately from the audio components. After installation, the one-piece and two-piece approaches both facilitate the flexible removal of the audio components from the mounting hardware.

### RELATED PATENT DOCUMENTS

This is a conversion of U.S. Provisional Patent Application Serial No. 60/435,103, entitled “Flush Mount Speaker System,” and filed on Dec. 20, 2002, to which priority is claimed under 35 U.S.C. §119.

### FIELD OF THE INVENTION

The present invention relates generally to audio speaker systems and more particularly to audio speakers and a mounting arrangement and approach therefor.

### BACKGROUND OF THE INVENTION

Audio speakers are used in a variety of applications ranging from consumer audio speaker systems to professional applications such as those implemented for theatrical and other entertainment venues. For many of these applications, audio speakers deliver one or more audio channels with diverse frequency and volume requirements. For example, an audio speaker with a woofer cone delivers low frequency audio while a tweeter cone delivers high frequency audio. In general, audio speakers need to deliver clear, distortion free audio across a wide frequency and volume range without intruding upon the visual appeal of a consumer or professional application.

In some applications, speakers are mounted into walls, ceilings or other building structure. The aesthetic nature and space-saving characteristics of flush and/or recess mounted in-wall/ceiling speakers has lead to significant growth in their popularity. These applications typically involve installing a speaker in a surface opening (e.g., wall or ceiling) and attaching the speaker to some structure either in the opening or to a surface (e.g., to building framework and/or to wall or ceiling material such as drywall). Traditional one-piece designs combine the sound-related portions of a speaker (sound-creating components and associated structure) and mounting hardware (e.g., framework, fasteners) into a single unit. For two-piece designs, mounting hardware is attached to the structure (wall, ceiling or framework) where the speaker is to be installed and the sound-related portions are coupled to the mounting hardware. The sound-related portions of a speaker typically include a baffle that protects speaker components such as cones (e.g., tweeter and woofer cones) and associated circuitry from physical damage. In some instances, baffles are also used to minimize audio interference and vibrations.

In general, one-piece audio speaker systems can be installed in a relatively shorter time than two-piece audio systems. Typical installations involve creating an opening in which a one-piece speaker unit (frame secured to a baffle) is inserted, with one or more types of fasteners used to couple the speaker unit to the installation area. While one-piece designs are relatively simply installed, they are less adaptable for various needs of many applications. For example, when a building is under construction, it is often desirable to install audio systems during a construction phase that does not offer theft security (e.g., early stages of construction often may not restrict access to speaker installations when exterior doors and locks have not been installed). In this regard, the installation of one-piece designs before the installation location is secure introduces the risk of theft.

Two piece audio speaker systems have been found useful for a variety of instances. Specifically, the separation of audio-creating portions of a two-piece speaker arrangement has also been found useful for a variety of instances. For example, where theft security is not present or weak during building construction, relatively inexpensive mounting hardware can be installed at an early stage of construction with the audio-related components being installed at a later time, after the location is secure. In addition, the mounting hardware and/or cover (e.g., speaker grille) can be painted separately from the audio-creating portions (or installed after painting). In addition, when audio-creating portions of a speaker arrangement are removed for painting, service or replacement, the two-piece design facilitates the removal without necessarily removing the mounting hardware, saving time and also inhibiting damage that can occur when mounting hardware is removed. Moreover, when a speaker grille is used, the grille can be replaced to cover the hole in which the speaker arrangement is mounted when the audio-related portions are removed (e.g., being serviced).

While exhibiting many benefits, two-piece audio speaker systems typically involve a two-step installation approach in which mounting hardware as a frame is first installed at an opening created at the installation location. After the frame is mounted, a second piece including the sound-creating portions of the speaker is attached to the mounted frame. Typically, the frame is mounted with a first set of fasteners and the audio-related portions are coupled to the frame with a second set of fasteners. At times, this two-step approach may not be desirable and may take more time, relative to a one-step approach.

The above and other difficulties related to speaker systems and their installation have presented challenges to their installation, removal and servicing.

### SUMMARY OF THE INVENTION

The present invention is directed to overcoming the above-mentioned challenges and others related to the types of approaches and implementations discussed above and in other applications. The present invention is exemplified in a number of implementations and applications, some of which are summarized below.

According to an example embodiment of the present invention, a speaker system includes baffle, frame and adjustable securing elements that facilitate installation of the speaker system into a structural opening such as a wall or ceiling. The baffle includes at least one audio-speaker component such as an audio cone adapted for producing sound. The frame includes protruding backside members adapted to be secured to the baffle and to the structural opening via supporting structure at the opening such as building materials, wall materials or studs. The adjustable securing elements (e.g., clamping screws or bolts, barbed-shaft members or twist locks) are received by at least one of the protruding backside members and therein secure the baffle to the frame as well as to the supporting structure.

According to another example embodiment of the present invention, a speaker system includes an assembly including a baffle secured to a frame using adjustable-securing members. The frame includes protruding backside members and associated frame channels, with the adjustable-securing members being installed in respective ones of the frame channels. Member ends of the adjustable-securing members are adapted to secure, in response to being adjusted to an external object located on a side of frame opposite the baffle.

In another example embodiment of the present invention, a speaker apparatus including an assembly and frame is installed to a target location using adjustable-securing members. The assembly includes a baffle secured to a frame via the adjustable-securing members, the frame including protruding backside members and associated frame channels. The adjustable-securing members are installed in respective ones of the frame channels and further have member ends adapted to secure, in response to being adjusted, to an external object located on a side of frame opposite the baffle. The assembly is positioned at a target installation location and the adjustable-securing members are adjusted until the member ends secure the assembly to the external object and therein install the speaker apparatus at the target installation location.

In another example embodiment of the present invention, a speaker apparatus is installed using a two-piece approach. The frame is installed at an identified surface area, with each of a first set of adjustable-securing members being inserted into respective frame holes aligned with a backside surface element. Each of the first set of adjustable-securing members are turned to secure the frame to the backside surface element and the surface opening area. A baffle is then installed into the frame and, with a frame key aligned with a baffle key; each of a second set of adjustable-securing members is inserted into respectively aligned baffle holes, frame holes, and protruding backside members of the frame having a channel. Each of the second set of adjustable-securing members are adjusted and secured to an object inserted into the respective channel of each protruding backside member. Each engaged object is thus drawn into the channel of each protruding backside member at least until a first portion of each engaged object secures to a portion of each protruding backside member with sufficient force to secure the baffle to the frame. Each of the second set of adjustable-securing members is then further adjusted to rotate each object and further draw each object into the channel of each protruding backside member at least until a second portion of each engaged object contacts the backside of the surface opening area.

According to another example embodiment of the present invention, a speaker apparatus is installed using another two-piece installation approach. A frame is inserted inserting a frame into a surface opening area and each of a first set of screw-like members is inserted into respective frame holes aligned with a backside surface piece. Each of the first set of screw-like members are turned to secure the frame to the backside surface piece and the surface opening area. A baffle is inserted into the frame, a frame key is aligned with a baffle key and each of a second set of screw-like members is inserted into respectively aligned baffle holes, frame holes, and protruding backside members of the frame, each protruding backside member have a channel. Each of the second set of screw-like members is turned to secure to an object inserted into the respective channel of each protruding backside member. Each engaged object is drawn into the channel of each protruding backside member at least until a first portion of each engaged object secures to a portion of each protruding backside member with sufficient force to secure the baffle to the frame. Each of the second set of screw-like members is further turned to rotate each object and further drawing each object into the channel of each protruding backside member at least until a second portion of each engaged object contacts the backside of the surface opening area.

The above summary of the present invention is not intended to describe each illustrated embodiment or implementation of the present invention. The figures and the associated discussion that follows more particularly exemplify these embodiments.

### BRIEF DESCRIPTION OF THE DRAWINGS

The invention may be more completely understood in consideration of the detailed description of various embodiments of the invention in connection with the accompanying drawings, in which:

FIG. 1 illustrates an audio speaker system in accordance with various embodiments of the present invention;

FIG. 2A and FIG. 2B show alternate views of an arrangement adapted for a one-piece and/or two-piece approach, in accordance with another example embodiment of the present invention;

FIG. 3 illustrates a two-piece audio speaker system, according to another example embodiment of the present invention; and

FIG. 4 illustrates a one-piece design installation, according to another example embodiment of the present invention.

While the invention is amenable to various modifications and alternative forms, specifics thereof have been shown by way of example in the drawings and will be described in detail. It should be understood, however, that the intention is not necessarily to limit the invention to the particular embodiments described. On the contrary, the intention is to cover all modifications, equivalents, and alternatives falling within the spirit and scope of the invention as defined by the appended claims.

### DETAILED DESCRIPTION

The present invention is believed to be applicable to a variety of audio applications including those utilizing an audio speaker system. Various example embodiments of the present invention have been found to be particularly advantageous for applications in which a recessed or flush mounted speaker system is installed or removed from a wall/ceiling. In addition, one-piece and/or two-piece designs are readily implemented, thus realizing benefits attributable to each design. The present invention is not necessarily limited to such applications; various aspects of the invention may be appreciated through a discussion of various examples using this context.

According to an example embodiment of the present invention, an audio speaker system is adapted for installation as a one-piece unit, with integrated frame and baffle (speaker unit) structures adapted for installation into a wall/ceiling aperture (opening). The structural shape of the speaker system (e.g., the fame and baffle) is selected for similarly with shaped features such as square, rectangle, or circle features that match an opening type for which the speaker system is to be installed. The baffle includes one or more of holes, a bridge, speaker cones, drivers and a crossover circuit for separating an audio signal into the appropriate speaker cones. The frame typically includes protruding backside members and fastener holes. A fastener piece having a threaded cavity is inserted into the channel of each protruding backside member for coupling with threaded fasteners. The speaker unit is attached to the wall/ceiling aperture with screws that pass through the holes in the baffle, the first set of holes in the frame and the protruding backside members. The screws also engage the threaded cavity of the fastener piece inserted into the channel of the protruding backside members. After being initially set on the frame step to retain the baffle to the frame with sufficient force to safely secure the baffle to the frame to form a speaker unit, an initial clockwise turning of the screws causes a portion of the fastener piece to release. Further clockwise turning of the same screws causes each object to rotate and come in contact with a portion of the backside of a wall/ceiling area with sufficient force to safely secure the speaker unit to the wall/ceiling, thus completing the one-piece design installation.

According to another example embodiment of the present invention, an audio speaker system is adapted for installation as a two-piece design, with a frame adapted for coupling to a wall/ceiling aperture and a baffle adapted for coupling to the frame. The frame is installed directly to the wall/ceiling area (e.g., with wood studs) or secured with a backside bracket, bars, or other supporting structure. The frame, baffle and optional protruding backside member are implemented with shape characteristics for the particular implementation and desired aperture shape in a wall/ceiling area in which they are to be installed. The baffle and frame include elements similar to that discussed in connection with the one-piece example discussed above, with a fastener piece having a threaded cavity similarly being inserted into the channel of a support member (e.g., the protruding backside member) for coupling with threaded fasteners. The protruding backside member is adapted for securing (fastening) to the backside of a wall/ceiling aperture. The frame is secured to the front of the wall/ceiling aperture with threaded fasteners and the baffle is similarly coupled to the frame.

After the frame is secured, the baffle is attached to the wall/ceiling aperture and frame with screws that pass through openings in the baffle, the frame and the protruding backside member, and engage the threaded cavity of a fastener piece inserted into the channel of the protruding backside members. The protruding backside member is initially set to retain the baffle and frame by friction contact. Initial clockwise turning of the screws causes rotation off the initial setting, thereby retracting into the channel until contact is made with the backside of a wall. Further clockwise turning of the screws causes a portion of the fastener piece to rotate and come in contact with a portion of the protruding backside member or with a backside of wall/ceiling area if the protruding backside member is not used. The rotation of the fastener piece and associated contact effects sufficient force to attach the speaker unit to the wall/ceiling, thus completing the second part of the two-piece design installation. In addition, with this approach, the baffle can be removed for repair without removing the frame and with a simple counterclockwise turning of the screws. Also, the baffle can be installed at a later time for a non-secure application, such as new home residences (e.g., where it is desirable to install the frame, but not the baffle for security purposes). The baffle can easily be removed from the wall/ceiling aperture by a counterclockwise turning of the screws.

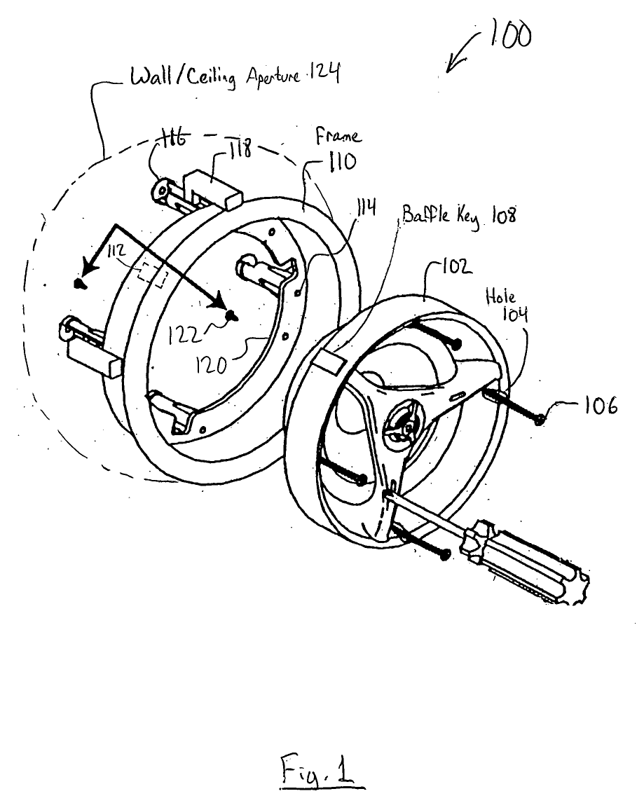

Turning now to the figures, FIG. 1 shows an audio speaker system 100, according to another example embodiment of the present invention. The audio speaker system 100 includes a baffle 102, a frame 110, a first set of screws 106 and a second set of screws 122. The baffle 102 typically includes holes 104 for receiving screws 106, and a baffle key 108 for alignment with a frame key 112. The baffle 102 may also include one or more speaker cones, one or more drivers, a bridge, and a crossover circuit for sending an appropriation frequency range of an audio signal to the appropriate speaker cone. The frame 110 typically includes the frame key 112, holes 114 for receiving screws 106, protruding backside members 116 for receiving screws 106, U-shaped objects 118 for attachment to the protruding backside members 116 and holes 120 for receiving screws 122.

The system 100 is adaptable for implementation with one-piece and/or two-piece installation approaches. In the one-piece approach, the frame 102 and baffle 110 are adapted for securing to a wall/ceiling aperture 124. In the two-piece approach, the frame 102 is secured to the wall/ceiling aperture 124 and the baffle 110 couples to the frame 102. In addition, an installed one-piece design can be converted into a two-piece design and vice versa. The frame 102 and baffle 110 are secured to a wall/ceiling aperture 124 in a recessed or partially recessed manner. The baffle 110, frame 102, and wall/ceiling aperture 124 each have a circular shape in FIG. 1; however, various example embodiments are adaptable to a multitude of shapes such as circular, square and rectangular shapes. The unique dual purpose of the screws 106 facilitates applicability to both one-piece and two-piece installations, generating a flexible and readily implemented speaker system.

When implemented with a one-piece approach (e.g., pre-assembled at the factory), the baffle 102 is adapted for securing to the frame 110 and, correspondingly, to the wall/ceiling aperture 124 to which the frame is secured. The baffle 102 is inserted into the frame 110 by first aligning the baffle key 108 with the frame key 112. Screws 106 are then inserted into the holes 104 for the baffle 102, holes 114 of the frame 110, and protruding backside members 116. The screws 106 are turned in a clockwise manner to engage a threaded cavity of a first side of each U-shaped object 118, which slides partially into a channel of each protruding backside member 116. After the first sides of each U-shaped object 118 are sufficiently engaged by the clockwise turning of the screws 106, the bases of each U-shaped object 118 contact a portion of the protruding backside members 116 with a sufficient frictional force to secure the baffle 102 to the frame 110.

After the baffle 102 is secured with the frame 110, the speaker unit (baffle with frame) can be inserted into the wall/ceiling aperture 124. The outer ledge of the frame 110 rests on the front side of the wall/ceiling area adjacent to the wall/ceiling aperture 124 and the remainder of the frame 110 and baffle 102 are inserted into the wall/ceiling aperture 124. A further clockwise turning of the screws 106 causes each U-shaped object 118 to rotate such that the bases of each U-shaped object is no longer in contact with the protruding backside members 116. However, the threaded first sides are drawn further within each U-shaped object 118 until the second sides of each U-shaped object contact the backside of the wall/ceiling area immediately adjacent to the wall/ceiling aperture 124 with a sufficient frictional force to secure the baffle 102 and frame 110 unit to the wall/ceiling. A backside bracket or bars are optionally installed to the back of the wall/ceiling area with a similar effect, with each U-shaped object 118 contacting the backside bracket or bars instead of the wall/ceiling area.

When implemented with a two-piece approach, the frame 110 is secured to a wall/ceiling aperture 124 and the baffle 102 is then secured to the frame 110 and wall/ceiling aperture 124. The frame 110 is secured to the wall/ceiling aperture directly (e.g., to wood studs) or with a backside bracket, bars, or some other means. The backside bracket attaches to wood studs, a flange piece, or some other object. For example, the frame 110 may be secured to a backside bracket and wall/ceiling aperture 124 with screws 122 via holes 120. The outer ledge of the frame 110 rests on the front side of the wall/ceiling area adjacent to the wall/ceiling aperture 124 and the remainder of the frame 110 is inserted into the wall/ceiling aperture 124.

The baffle 102 is secured to the frame 120 in a manner similar to that described above for the one-piece design, with the frame having been first attached to the wall/ceiling aperture 124 before securing the baffle to the frame. The baffle 102 is inserted into the frame 110 by aligning the baffle key 108 with the frame key 112. The screws 106 are inserted into the holes 104 for the baffle 102, holes 114 of the frame 110, and the protruding backside members 116, which align with the holes 114 and 104. The screws 106 are turned in a clockwise manner to engage a threaded cavity of a first side of each U-shaped object 118, which slides partially into a channel of each protruding backside member 116. After the first sides of each U-shaped object 118 are sufficiently engaged by the clockwise turning of the screws 106, the bases of each U-shaped object contact a portion of the protruding backside members 116 with a sufficient frictional force to secure the baffle 102 to the frame 110.

A further clockwise turning of the screws 106 causes each U-shaped object 118 to rotate such that the bases of the U-shaped objects are no longer in contact with the protruding backside members 116. However, the threaded first sides are drawn further within each protruding backside member 116 until the second side of the each U-shaped object 118 contacts the backside of the wall/ceiling area immediately adjacent to the wall/ceiling aperture 124. The contact between each U-shaped object 118 and the backside of the wall/ceiling area is effected with sufficient frictional force to secure the baffle 102 and frame 110 unit to the wall/ceiling.

In accordance with another example embodiment in an application where a rough-in bracket had been used, an audio speaker system is installed as a one-piece design, removed as a one-piece design, and then reinstalled as a two-piece design for a residential application. This approach is useful, for example, where a residential or business user initially wants the speaker system quickly installed (as facilitated via the one-piece design), and later has a need to remove the speaker portion. Accordingly, a one-piece design installation as discussed above in connection with FIG. 1 is used and implemented with four screws 106. When the baffle 102 is to be removed (e.g., sent out for repair), the baffle 102 and frame 110 are removed from the wall/ceiling aperture 124 and detached from each other. The frame 110 and a speaker grill that cover the frame and opening in which the frame is attached can be reinstalled on the wall/ceiling aperture 124 as discussed above in connection with the two-piece approach so that a gaping hole does not exist. When the baffle is to be reinstalled, a two-piece design installation approach such as that discussed above involves securing the repaired baffle 102 to the frame 110 as discussed above.

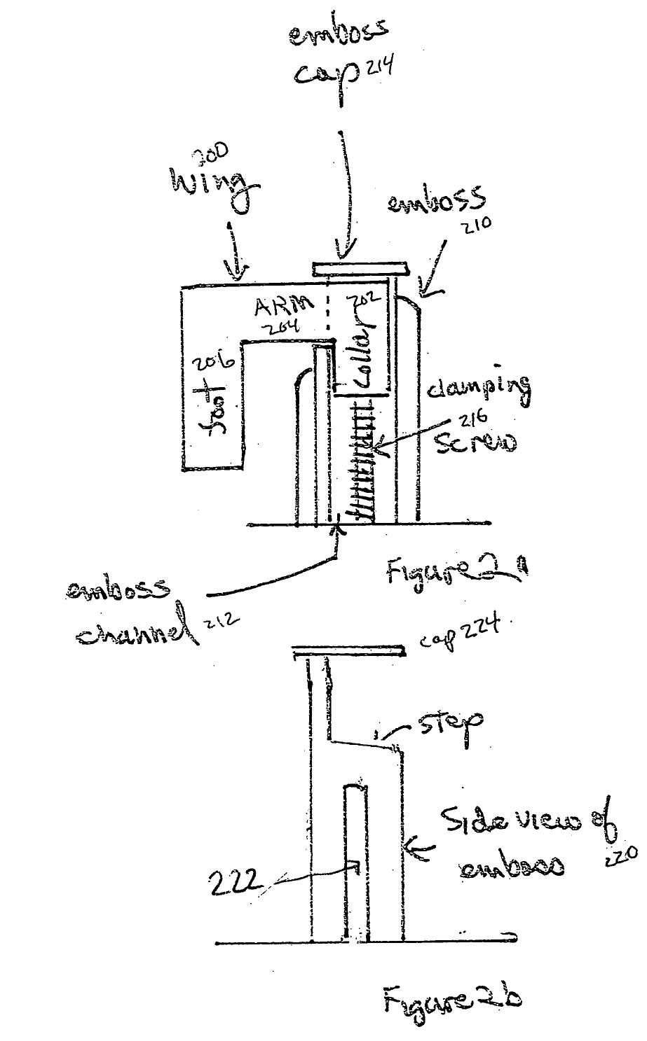

FIG. 2A and FIG. 2B illustrate alternate views of an example mechanism and approach that can be implemented for achieving a one-piece and/or two-piece design installation in connection with various embodiments of the present invention. For example, the mechanism and approach shown in FIGS. 2A and 2B may be implemented in connection with the approach shown and discussed with FIG. 1.

Beginning with FIG. 2A, a wing is coupled with a protruding backside emboss structure from a frame. A wing 200 includes a collar 202, an arm 204, and a foot 206 that may, for example, collectively represent similar functionality to the first side, base, and second side of a U-shaped object 118 shown in FIG. 1. An emboss 210, having similar functionality, e.g., as a protruding backside member 116 in FIG. 1, includes an emboss channel 212 and an emboss cap 214. A clamping screw 216, functionally similar to a screw 106 in FIG. 1, is inserted into an emboss channel and optionally engages a threaded cavity of a collar 202. A clockwise turning of the clamping screw 216 engages the threaded cavity of the collar 202, thus pulling the wing 200 downwards into the emboss channel 212. A counterclockwise turning of the clamping screw 216 disengages the threaded cavity of the collar 202, thus pushing the wing 200 upwards out of the emboss channel 212.

Referring now to FIG. 2B, emboss 220 (e.g., emboss 210 of FIG. 2A) protrudes from the backside of a frame and includes an emboss channel 222, an emboss cap 224 and an emboss step 226. The emboss step 226 slopes downwards, which facilitates the engagement of fasteners. For instance, a clockwise turning of a clamping screw 216 engages the threaded cavity of the collar 202 as shown in FIG. 2A. The collar 202 moves downwards into the emboss channel 212 until the arm 204 contacts the emboss step 226 with sufficient frictional force to secure, e.g., a baffle to a frame in a manner similar to the securing of baffle 102 to a frame 110 in FIG. 1. A further clockwise turning of the clamping screw 216 causes the wing 200 to slide off the sloped emboss step 226 and rotate in a clockwise direction around the axis of the emboss channel 212 as shown in FIG. 2A. The collar 202 is pulled further into the emboss channel 212 until the foot 206 contacts the backside of a wall/ceiling area with sufficient frictional force to secure, e.g., a baffle 102 to a frame 110 to the backside of a wall/ceiling area adjacent to a wall/ceiling aperture 124 as shown in FIG. 1. A counterclockwise turning of the clamping screw 216 pushes the wing 200 out of the emboss channel 212 until the wing 200 contacts the emboss cap 214. The clamping screw 216 then disengages from the wing 200 and the baffle 102 is separated from the frame 110.

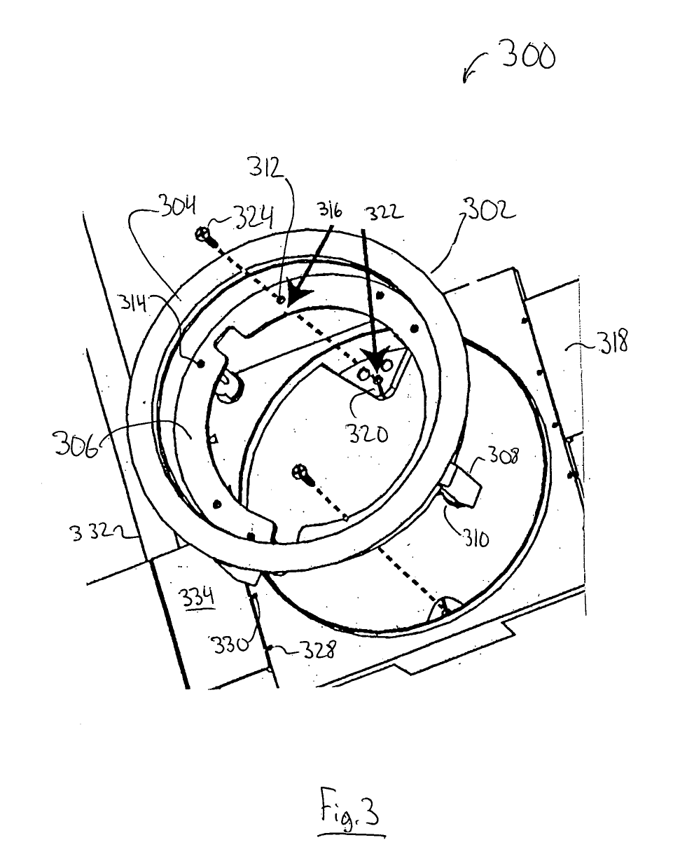

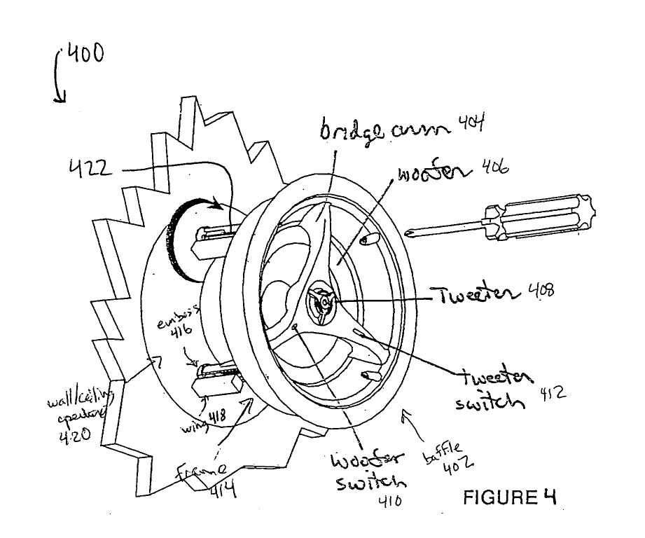

The wing 200 coupled with the emboss 210 and clamping screw 216 as discussed above provide a mechanism for securing an audio speaker arrangement to a wall/ceiling area for a variety of implementations. FIG. 3 and FIG. 4 illustrate example such implementations of the present invention enabled by a wing 200 coupling with an emboss 210 and clamping screw 216.

Beginning with FIG. 3, a two-piece speaker system arrangement 300 includes a frame 302 adapted to secure to a wall/ceiling area directly (e.g., with wood studs) and/or with a backside bracket, bars, or some other means and then securing a baffle to the frame. The two-piece speaker system arrangement 300 includes the frame 302, a bracket 318, frame-bracket screws 324 and clamping screws, and is further adapted to couple with a baffle similar to, for example, baffle 102 of FIG. 1. The frame 302 includes a frame outer ledge 304, a frame inner ledge 306, embosses 308, wings 310, holes 312 for receiving frame-bracket screws 324, holes 314 for receiving clamping screws, and a key 316. Holes 320 in the bracket 318 facilitate receiving frame-bracket screws 324, a key 322 for alignment with the key 316, bracket holes 328 for receiving bracket screws 330. Additional (or fewer) holes and screws can be used to meet the needs of particular applications to which the speaker system arrangement 300 is applicable, depending upon variables such as the available material, weight of the baffle and type of material to which the arrangement is mounted.

The bracket 318 is installed behind a present or future wall/ceiling area (e.g., drywall) by inserting bracket screws 330 into bracket holes 328 along the perimeter of the bracket 318 and securing to wood studs 332 or a flange piece 334. The flange piece 334 provides a flexible manner in which to mount a bracket without actually mounting to a stud. For new construction applications, the bracket 318 facilitates installation prior to a wall/ceiling material, such as drywall, being installed. After the wall/ceiling material is in place and an aperture in the wall/ceiling is opened, the frame 302 is inserted into the aperture such that the frame inner ledge 306 is recessed within the aperture and the frame outer ledge 304 contacts the front side of the wall/ceiling area. The frame 302 attaches to the bracket 318 by aligning the key 316 with the key 322 and then inserting frame-bracket screws 324 into the holes 312 and the holes 320. The bracket 318 is optional for the two-piece design installation as the frame 302 can directly attach to wood studs 332 or a flange piece 334 using, for example, drywall screws or other similar fastener. While the frame 302 and bracket 318 are shown with circular apertures in FIG. 3, various other shapes are selectively implemented in connection with this example embodiment.

After the frame 302 and optional bracket 318 are secured to a wall/ceiling area, a baffle such as baffle 102 of FIG. 1 can be secured to the frame 302. A baffle key aligns with the key 316 of the frame 302 and the clamping screws are inserted into the holes of the baffle and holes 314 for the frame 302. The clockwise turning of clamping screws engages threaded collar cavities of wings 310 that are pulled into channels of embosses 308. The embosses 308 protrude from the backside of the frame 302 and may be functionally implemented in a manner similar to that of the embosses 210 shown in FIG. 2A. In addition, the wings 310 may be implemented with functionality similar to that of the wings 200 shown FIG. 2A. A clockwise turning of the clamping screws causes the wings 310 to slide off the sloped emboss steps and rotate in a clockwise direction around the axis of the emboss channels. The collars of the wings 310 are pulled further into each emboss channel until the feet of the wings 310 contact the backside of a wall/ceiling area with sufficient frictional force to secure a baffle to a frame 302 to the backside of a wall/ceiling area adjacent to a wall/ceiling aperture.

In another example embodiment of the present invention, the approach and arrangement shown in FIG. 3 and discussed above is implemented for temporarily removing and subsequently reinstalling a portion of a speaker system. For instance, when a homeowner wants to paint the frame 302 and grill of a speaker unit without accidentally painting the baffle attached thereto, or when the baffle malfunctions, the baffle is desirably removed from the frame 302. In this regard, the frame 302 can be left in place (or pre-installed without a baffle) for painting, or left in place if the baffle is to be removed for service or repair, using the above approach for attaching (and in reverse for removing) the clamping screws. With this approach, baffle repair, home remodeling requiring new frame painting or various other needs are addressed.

FIG. 4 shows a one-piece speaker arrangement 400, according to another example embodiment of the present invention. The one-piece speaker arrangement 400 includes a baffle 402, a frame 414 and clamping screws 422. The baffle 402 includes a bridge arm 404, a woofer cone 406, a tweeter cone 408, a woofer switch 410, a tweeter switch 412, holes for receiving clamping screws 422, a crossover circuit, and drivers. The frame 414 includes embosses 416, wings 418, and holes (not shown) for receiving clamping screws 422.

The baffle 402, along with the frame and the grill, protect the speaker cones from physical damage and is designed in shape and material composition to minimize audio interference and unwanted vibrations (e.g., backside vibrations) generated from a vibrating speaker cone. The bridge arm 404 provides a manner in which to mount a tweeter cone for optimal audio dispersion characteristics while maintaining compact baffle dimensions. Also, the bridge arm 404 allows easy access to a woofer switch 410 and a tweeter switch 412. A crossover network separates the frequency components of an audio signal and sends the separated signals (e.g., a high frequency signal and a low frequency signal) into the appropriate speaker cone. For example, a tweeter cone 408 typically delivers high frequency audio while a woofer cone 406 delivers low frequency audio. The stable, easy to reach and grip surface of the bridge arm 404 facilitates easy installation of the baffle 402 with the frame 414.

For a one-piece design installation, the baffle 402 and frame 414 are aligned to each other with keys in a manner similar to that shown and discussed in connection with FIG. 1. Clamping screws are inserted into aligned holes of the baffle 402 and the frame 414. A clockwise turning of clamping screws 422 causes the wing to release from its initial step-secured position and then engage a threaded cavity of a collar of each wing 418 that is pulled into an emboss channel of an emboss 416. The embosses 416 protrude from the backside of the frame 414. The embosses 416 exhibit similar functionality as the embosses 210 from FIG. 2A. The wings 418 exhibit similar functionality as the wings 200 from FIG. 2A. The arms of the wings 418 contact the steps of the embosses 416 with sufficient frictional force to secure the baffle 402 to the frame 414.

After inserting the baffle 402 and frame 414 unit into a wall/ceiling aperture 420, a further clockwise turning of the clamping screws 422 causes the wings 418 to slide off the sloped emboss steps and rotate in a clockwise direction around the axis of each emboss channel. The collars of the wings 418 are pulled further into the emboss channels until the feet of the wings 418 contact the backside of a wall/ceiling area with sufficient frictional force to secure the baffle 402 to the frame 414 to the backside of the wall/ceiling area adjacent to the wall/ceiling aperture 420. A backside bracket or bars can be installed to the back of the wall/ceiling area with the same effect, except now the wings 418 contact the backside bracket or bars instead of the wall/ceiling area.

Other aspects and embodiments of the present invention will be apparent to those skilled in the art from consideration of the specification and practice of the invention disclosed herein. It is intended that the specification and illustrated embodiments be considered as examples only, with a true scope and spirit of the invention being indicated by the following claims.

What is claimed is:

1. A speaker system comprising:
a baffle with at least one audio-speaker component;
a frame having protruding backside members adapted to be secured to the baffle and to supporting structure at a surface area;
adjustable securing elements, wherein each adjustable securing element is to be received by at least one of the protruding backside members and therein secure the baffle to the frame; and
the baffle, frame, and adjustable securing elements screws adapted to permit a clamping of the baffle and frame to the surface area.

2. The speaker system of claim 1, wherein each of the adjustable securing elements includes a threaded shaft.

3. The speaker system of claim 1, wherein each of the adjustable securing elements is a screw-like member having a threaded shaft that turns to provide a clamping operation.

4. The speaker system of claim 1, wherein each of the adjustable securing elements includes a barbed-shaft member.

5. The speaker system of claim 1, wherein each of the adjustable securing elements includes a twist lock.

6. The speaker system of claim 1, wherein the adjustable securing elements are adapted for securing the frame to the surface area and for releasing the baffle from the frame while securing the frame to the

7. A speaker system, comprising:
an assembly including a baffle secured to a frame using adjustable-securing members;
the frame including protruding backside members and associated frame channels; and
the adjustable-securing members installed in respective ones of the frame channels and having member ends adapted to secure, in response to the adjustable-securing members being adjusted, to an external object located on a side of frame opposite the baffle.

8. The speaker system of claim 7, wherein the assembly is adapted to secured at a target installation location by adjusting the adjustable-securing members until the member ends secure the assembly to the external object.

9. The speaker system of claim 8, wherein each of the protruding backside members includes a collar portion connected to a wing portion, wherein the wing portion rotates to secure to the external object.

10. A method for installation of a speaker apparatus at a target installation location, the method comprising:
providing an assembly including a baffle secured to a frame using adjustable-securing members,
the frame including protruding backside members and associated frame channels,
the adjustable-securing members installed in respective ones of the frame channels and having member ends adapted to secure, in response to the adjustable-securing members being adjusted, to an external object located on a side of frame opposite the baffle;
positioning the assembly at a target installation location; and
adjusting the adjustable-securing members until the member ends secure the assembly to the external object, and therein installing the speaker apparatus at the target installation location.

11. The method of claim 10, wherein the external object is part of a wall of the target installation location.

12. The method of claim 10, wherein each of the protruding backside members includes a collar portion connected to a wing portion, wherein the wing portion rotates to secure to the external object.

13. A method for installation of a speaker apparatus, the method comprising:
installing a frame at an identified surface area;
inserting each of a first set of adjustable-securing members into respective frame holes aligned with a backside surface element;
turning each of the first set of adjustable-securing members and therein securing the frame to the backside surface element and the surface opening area;
installing a baffle into the frame;
aligning a frame key with a baffle key;
inserting each of a second set of adjustable-securing members into respectively aligned baffle holes, frame holes, and protruding backside members of the frame, each protruding backside member have a channel;
adjusting each of the second set of adjustable-securing members and therein securing to an object inserted into the respective channel of each protruding backside member, wherein each engaged object is drawn into the channel of each protruding backside member at least until a first portion of each engaged object secures to a portion of each protruding backside member with sufficient force to secure the baffle to the frame; and
further adjusting each of the second set of adjustable-securing members, thus rotating each object and further drawing each object into the channel of each protruding backside member at least until a second portion of each engaged object contacts the backside of the surface opening area.

14. The method of claim 15 wherein the backside surface element includes at least one of: wood studs, flange piece, and bracket.

15. The method of claim 15 wherein each of the first set of adjustable-securing members is a screw.

16. The method of claim 15 wherein each of the first set of adjustable-securing members does not include a threaded shaft.

17. The method of claim 15 wherein each of the second set of adjustable-securing members includes a threaded shaft.

18. The method of claim 15 wherein each of the second set of adjustable-securing members does not include a threaded shaft.

19. A method for installation of a speaker apparatus, the method comprising:
inserting a frame into a surface opening area;
inserting each of a first set of screw-like members into respective frame holes aligned with a backside surface piece;
turning each of the first set of screw-like members and therein securing the frame to the backside surface piece and the surface opening area;
inserting a baffle into the frame;
aligning a frame key with a baffle key;
inserting each of a second set of screw-like members into respectively aligned baffle holes, frame holes, and protruding backside members of the frame, each protruding backside member having a channel;
turning each of the second set of screw-like members and therein securing to an object inserted into the respective channel of each protruding backside member, wherein each engaged object is drawn into the channel of each protruding backside member at least until a first portion of each engaged object secures to a portion of each protruding backside member with sufficient force to secure the baffle to the frame; and
further turning each of the second set of screw-like members, thus rotating each object and further drawing each object into the channel of each protruding backside member at least until a second portion of each engaged object contacts the backside of the surface opening area.

20. A flush mounted speaker system comprising:
means for both clamping a speaker component to a frame to form a one piece assembly and clamping the one piece assembly to a recessed wall or ceiling area; and
means for releasing the speaker component from the frame.

21. The system of claim 20, wherein the means for releasing the speaker component from the frame is configured and arranged to release the speaker component from the frame while clamping the frame to the recessed wall or ceiling area.
